(19) United States
(12) Patent Application Publication
(10) Pub. No.: US 2022/0375715 A1
(43) Pub. Date: Nov. 24, 2022

(54) CHARGED PARTICLE INSPECTION SYSTEM AND METHOD USING MULTI-WAVELENGTH CHARGE CONTROLLERS

(71) Applicant: ASML NETHERLANDS B.V., Veldhoven (NL)

(72) Inventors: Jian ZHANG, San Jose, CA (US); Ning YE, San Jose, CA (US); Yixiang WANG, Fremont, CA (US); Jie FANG, San Jose, CA (US)

(73) Assignee: ASML NETHERLANDS B.V., Veldhoven (NL)

(21) Appl. No.: 17/771,761

(22) PCT Filed: Oct. 21, 2020
(86) PCT No.: PCT/EP2020/079672

§ 371 Date: Apr. 25, 2022

Related U.S. Application Data
(60) Provisional application No. 62/925,320, filed on Oct. 24, 2019.

(51) Int. Cl. H01J 37/22; H01J 37/28

(52) U.S. Cl. CPC H01J 37/226; H01J 37/28; H01J 2237/24564; H01J 2237/24585

(57) ABSTRACT

An apparatus for and a method of inspecting a substrate in which a charged particle beam is arranged to impinge on a portion of the substrate and a first light beam having a first wavelength and a second light beam having a second wavelength different from the first wavelength are also arranged to impinge on the portion of the substrate.

### CROSS-REFERENCE TO RELATED APPLICATIONS

This application claims priority of U.S. application 62/925,320 which was filed on Oct. 24, 2019, and which is incorporated herein in its entirety by reference.

### FIELD

The present disclosure relates to charged particle inspection systems and methods utilizing charge controllers to control electrical and/or thermal properties at a portion of an article being inspected.

### BACKGROUND

Improvements in semiconductor manufacturing technology have allowed for increasing the density of integrated circuits and packing more transistors on a given surface area or in a given volume of a wafer to form a semiconductor devices. Increasing transistor density has led to the need for systems and methods to provide for higher resolution wafer inspection. In particular, defects may occur during the various stages of semiconductor device manufacturing processes. It is important to identify any such defects accurately, efficiently, and as early as possible.

Generally, a process for manufacturing semiconductor devices comprises forming layers of a variety of materials on or in the substrate of each semiconductor device; photo-processing, masking and forming circuit patterns on the semiconductor device; and removing or etching portions of the layers to form the semiconductor device. Such semiconductor devices are manufactured by repeating these and other operations on each device of a semiconductor wafer. Better manufacturing techniques have allowed for microfabrication, resulting in features that are much less discernible by most observation tools. In view of this, charged particle beam inspection systems, e.g. scanning electron microscopes (SEMs), electron beam probers, and focused ion beam (FIB) systems, have been used.

Electron beam (e-beam) inspection is performed by scanning an electron beam over surface patterns of devices formed on a substrate and collecting the secondary electrons emanated from the surface patterns of scanned devices as inspection signals. The signals are processed and represented in grey levels to produce images of surface patterns of the scanned devices. The patterned surface contains pattern features which either form the electrical devices or directly/indirectly electrical connect to devices within the substrate. The obtained image shown in grey level contrast represents the difference in electrical charging voltages associated with the devices, connections, as well as the materials. The image is thus also known as a voltage contrast (VC) image. Abnormal grey levels, or abnormal VCs, are detected to identify defective devices or connections. For example, if a bright grey level shows up where a darker grey level should have been observed, it is deemed there exists a bright voltage contrast (BVC) defect. On the other hand, if a dark grey level shows up where a brighter grey level should have been observed, it is deemed there exists a dark voltage contrast (DVC) defect.

When the electron beam is scanned over the surface pattern of a device, charging may be induced and accumulate on the device. The resulting charging can be negative or positive, depending on the electron beam conditions (landing energy, beam current, etc.) used, as well as surface pattern materials. Particularly, for electron beam (e-beam) inspection tools designed to meet a larger beam current requirement, the quality of the acquired image will deteriorate due to the accumulated charges on the surface of the wafer sample. This makes it more difficult to identify critical defects.

In order to avoid this issue, a charge regulation technique is implemented to regulate charge conditions at the wafer surface. One such technique employs laser radiation to illuminate the wafer surface and so to control local charging through photoconductivity and/or the photoelectric effect. For example, the optical beam may either induce a photocurrent or stimulate a leakage current so that ground or substrate electrons migrate to the inspection site and neutralize a positive charge accumulated on the scanned surface of the device. This helps to drain off the accumulated positive charges on the scanned device. See, e.g., Y. Zhao et al., Optical beam enhanced defect detection with electron beam inspection tools, 2008 International Symposium on Semiconductor Manufacturing (ISSM), Tokyo, Japan, 2008, pp. 258-260, which is incorporated herein by reference.

### SUMMARY

The following presents a simplified summary of one or more embodiments in order to provide a basic understanding of the embodiments. This summary is not an extensive overview of all contemplated embodiments, and is not intended to identify key or critical elements of all embodiments nor delineate the scope of any or all embodiments. Its sole purpose is to present some concepts of one or more embodiments in a simplified form as a prelude to the more detailed description that is presented later.

According to one aspect of an embodiment there is disclosed an apparatus for inspecting a substrate, the apparatus comprising a charged particle beam source arranged to project a charged particle beam onto a portion of the substrate, a first light source arranged to project a first beam of light having a first wavelength onto the portion of the substrate, and a second light source arranged to project a second beam of light having a second wavelength different from the first wavelength onto the portion of the substrate. The charged particle beam source may comprise an e-beam source. The first light source may comprise a first laser configured to generate the first beam and the second light source may comprise a second laser configured to generate the second beam. The first wavelength may be selected to penetrate the portion of the substrate to a first depth and the second wavelength may be selected to penetrate the portion of the substrate to a second depth different from the first depth. The first wavelength may be selected to generate thermal effects in the portion of the substrate and the second wavelength may be selected to modify electrical properties in the portion of the substrate. The first wavelength may be selected to generate thermal effects in the portion of the wafer at a first depth and the second wavelength may be selected to modify electrical properties in the portion of the wafer at a second depth different from the first depth. The apparatus may further comprise a beam combiner arranged to combine the first beam and the second beam into a single beam. The beam combiner may comprise a dichroic mirror. The beam combiner may comprise a trichroic prism.

According to another aspect of an embodiment there is disclosed a charged particle beam imaging apparatus for imaging a portion of a substrate, the apparatus comprising a source of a beam of charged particles, a charged particle optical system arranged to focus the beam onto a portion of the substrate, and an electromagnetic radiation optical system adapted to generate a first beam having a first wavelength and a second beam having a second wavelength different from the first wavelength and to focus the first and second beam on the portion of the substrate. The source of a beam of charged particles may comprise an e-beam source. The electromagnetic radiation optical system may comprise a first laser configured to generate the first beam and a second laser configured to generate the second beam. The first wavelength may be selected to penetrate the portion of the substrate to a first depth and the second wavelength may be selected to penetrate the portion of the substrate to a second depth different from the first depth. The first wavelength may be selected to generate thermal effects in the portion of the substrate and the second wavelength may be selected to modify electrical properties in the portion of the substrate. The first wavelength may be selected to generate thermal effects in the portion of the substrate at a first depth and the second wavelength may be selected to modify electrical properties in the portion of the substrate at a second depth different from the first depth. The apparatus may further comprise a beam combiner to combine the first beam and the second beam into a single beam. The beam combiner may comprise a dichroic mirror. The beam combiner may comprise a trichroic prism.

According to another aspect of an embodiment there is disclosed a charged a method of inspecting a substrate, the method comprising the steps of projecting a charged particle beam onto a portion of the substrate, projecting a first beam of light having a first wavelength onto the portion of the substrate, and projecting a second beam of light having a second wavelength different from the first wavelength onto the portion of the substrate. The step of projecting a charged particle beam onto a portion of the substrate may be performed using an e-beam source. The step of projecting a first beam of light having a first wavelength onto the portion of the substrate and the step of projecting a second beam of light having a second wavelength different from the first wavelength onto the portion of the substrate may be performed concurrently. The step of projecting a first beam of light having a first wavelength onto the portion of the substrate may be performed using a first laser and the step of projecting a second beam of light having a second wavelength different from the first wavelength onto the portion of the substrate may be performed using a second laser. The first wavelength may be selected to penetrate the portion of the substrate to a first depth and the second wavelength may be selected to penetrate the portion of the substrate to a second depth different from the first depth. The first wavelength may be selected to generate thermal effects in the portion of the substrate and the second wavelength may be selected to modify electrical properties in the portion of the substrate. The first wavelength may be selected to generate thermal effects in the portion of the wafer at a first depth and the second wavelength may be selected to modify electrical properties in the portion of the wafer at a second depth different from the first depth. The method may further comprise a step of combining the first beam and the second beam into a single beam. The combining step may be performed using at least one dichroic mirror. The combining step may be performed using at least one trichroic prism.

Further embodiments, features, and advantages of the present invention, as well as the structure and operation of the various embodiments are described in detail below with reference to accompanying drawings.

### BRIEF DESCRIPTION OF THE DRAWING

The accompanying drawings, which are incorporated herein and form part of the specification, illustrate the methods and systems of embodiments of the invention by way of example, and not by way of limitation. Together with the detailed description, the drawings further serve to explain the principles of and to enable a person skilled in the relevant art(s) to make and use the methods and systems presented herein. In the drawings, like reference numbers indicate identical or functionally similar elements.

FIG. 1 is a schematic diagram of a charged particle beam system such as could be used to according to aspects of an embodiment disclosed herein.

FIG. 2 illustrates an embodiment of a charged particle beam system incorporating a charge regulation module according to aspects of an embodiment disclosed herein.

FIG. 3A is a conceptual diagram illustrating the concept of two light having differing wavelengths penetrating to different depths in the substrate.

FIG. 3B is a conceptual diagram illustrating the concept of two light having differing wavelengths affecting different properties of a substrate.

FIG. 4 is a diagram showing an arrangement of multi-wavelength light sources according to an aspect of an embodiment.

FIG. 5 is a diagram showing an arrangement of multi-wavelength light sources according to an aspect of an embodiment.

FIG. 6 is a diagram showing an arrangement of multi-wavelength light sources according to an aspect of an embodiment.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details described below. In other instances, well-known structures and devices are shown in block diagram form in order to facilitate description of one or more embodiments. The following presents a simplified summary of one or more embodiments in order to provide a basic understanding of the embodiments. This summary is not an extensive overview of all contemplated embodiments, and is not intended to identify key or critical elements of all embodiments nor delineate the scope of any or all embodiments.

Examples of charged particle inspection systems include SEMs (Scanning Electron Microscopes), TEMs (Tunneling Electron Microscopes), STEMs (Scanning Tunneling Electron Microscopes), AFMs (Atomic Force Microscopes), or FIB (Focused Ion Beam) instruments. For defect inspection as applied to a silicon wafer, commercial e-beam inspection tools most often employ SEMs. The following discussion of preferred embodiments will therefore use SEMs as an example, but it will be understood that the concepts disclosed herein may be applicable to other types of charged particle inspection systems as well.

As mentioned, electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus one goal of the manufacturing process is to identify such defects quickly and reliably.

Thus it is typical to inspect the chip circuit structures at various stages of their formation. Inspection can be carried out using a scanning electron microscope (SEM), also referred to herein as e-beam inspection systems. An SEM can be used to image these extremely small structures, in effect, taking a “picture” of the structures. The image can be used to determine if the structure was formed properly and also if it was formed in the proper location.

As the name implies, SEMs use beams of electrons because such beams can be used to see structures that are too small to be seen by microscopes using light. The electrons in the beam, however, may cause a charge to accumulate at the surface of the substrate. This can interfere with obtaining a useful image. Also, for some devices portions of the circuit may lie beneath the surface of the substrate. It is potentially beneficial to be able to control physical properties such as electrical or thermal properties of the substrate and at different depths within the substrate.

One of several disclosures in this application is a system and method in which the portion of the substrate subjected to the electron beam is also subjected to two light beams of differing wavelengths. This affords the capability of control physical properties such as electrical or thermal properties of the substrate and at different depths within the substrate. Of course, this is an approximate description, and the actual details are set forth more completely and precisely below.

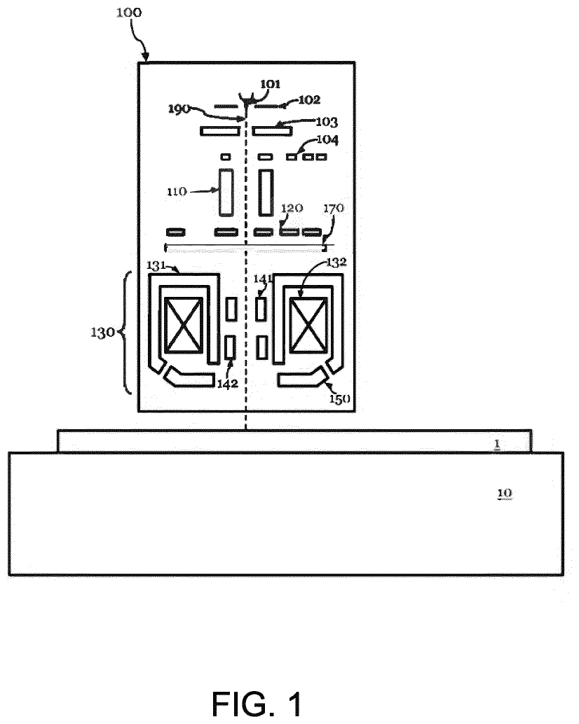

An SEM-based e-beam inspection tool is shown in FIG. 1. The SEM 100 includes an electron gun and a column, wherein the electron gun includes a tip 101, a Schottky suppressor electrode 102, an anode 103, a selectable Coulomb aperture plate 104, and a condenser lens 110. The tip 101, emitting a primary electron beam 190, can be a high temperature Schottky point cathode which is ZrO/W Schottky electrode. The Schottky suppressor electrode 102 provides a virtual source of the primary electron beam 190. The anode electrode 103 provides an electric field to extract electrons from the tip 101. Then, the primary electron beam 190 is then passed through the selectable Coulomb aperture plate 104 to reduce aberrations caused by Coulomb forces. The primary electron beam is then condensed by the condenser lens 110. The condenser lens 110 in the FIG. 1 is an electrostatic lens, but, for any person skilled in the art, one or more than one magnetic lens can also employed in the SEM 100.

The column in the SEM 100 includes a beam current plate 120, a detector 170, two deflectors 141 and 142, and an objective lens 130. The beam current plate 120 includes a plurality of apertures to permit a user to select a suitable beam current of the primary electron beam. The primary electron beam is then focused by the objective lens 130 on the wafer sample 1 supported by a stage 10. The sample 1 can be a mask for lithographic process, a silicon wafer, a GaAs wafer, a SiC wafer, or any other substrate for semiconductor process. As used herein the term “substrate” is intended to encompass all of these structures. The objective lens 130 in FIG. 1 is a magnetic lens which includes a coil 132 encompassed by a yoke 131. Two deflectors 141 and 142 deflect to the primary electron beam 190 to scan it across the wafer sample 1. An electrode 150 below the objective lens 130 can provide a retarding or immersion electric field for the primary electron beam 190. A potential can be applied to the stage 10 such that the landing energy of the primary electron beam 190 can be adjusted or controlled. The objective lens 130 illustrated in FIG. 1 may be of a type typically employed in an SEM, but variant designs and structures for specific purposes can be also applied, such as SORIL lens, for large FOV (Field Of View) inspection, as disclosed in U.S. Pat. No. 6,392,231.

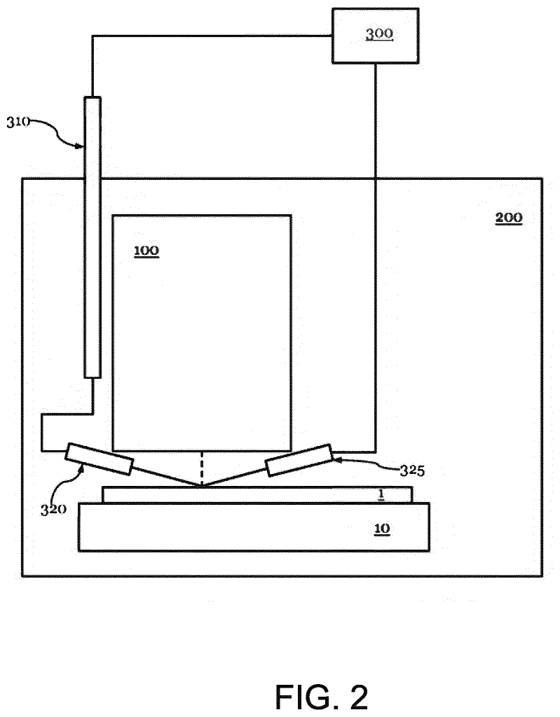

FIG. 2 shows an arrangement providing charge regulation wherein a laser 320 illuminates a portion of the sample 1 with electromagnetic radiation. The electromagnetic radiation is then reflected to a detector 325 which may be CCD (Charge-Coupled Device) or CMOS(Complementary Metal-Oxide-Semiconductor) sensor, among others. After the detector 325 receives signals from the laser 320, a controller 300 detects a location of the beam spot on the surface of the sample 1, calculates a predetermined position which is irradiated by the primary electron beam 190, and drives the laser 320 to illuminate the beam spot to the predetermined position via the transmission medium 310. The SEM 100, the laser 210, the detector 325, the wafer sample 1, and the stage 10 are all inside a vacuum chamber 200. The controller 300, may be a computer or ASIC (Application Specific Integrated Circuit), is positioned outside the vacuum chamber 200.

As mentioned, the charge controller generates a laser beam and projects the laser to the e-beam center at the sample. The laser radiation is usually applied to the sample surface to help to control the accumulation of charge on the sample during e-beam inspection. This laser beam changes the electron extraction rate of the materials, for example, by generating electrical effects in the materials (surface plasmons, changes of electrical fields) or generating thermal effects (heats/phonon vibrations) in the lattice of the semiconductors material in the sample. Thus, the signal/noise (S/N) ratio of the signal generated during an e-beam investigation can be improved by the interaction of photons and semiconductor materials.

The mitigating interaction of the electromagnetic radiation with the material depends in part on the wavelength of the electromagnetic radiation. According to an aspect of an embodiment, multiple sources of electromagnetic radiation are used, each having a different wavelength. This permits a wider range of interactions with the material both in terms of depth of interaction and in terms of type of interaction. For example, electromagnetic radiation having a first wavelength may have a penetration depth which is different from the penetration depth of electromagnetic radiation having a second wavelength different from the first wavelength. As another example, electromagnetic radiation having a first wavelength may interact with the material predominantly through electrical effects while electromagnetic radiation having a second wavelength different from the first wavelength may interact with the material predominantly through thermal effects. Thus a charge controller with multi-wavelength sources offers the possibility of an entire new range of inspection techniques

As stated broadly above, the purpose of the charge controller is to improve the S/N ratio of the signal generated during an e-beam investigation or inspection, the terms being used synonymously herein. In other words, the charge controller is used to increase the contrast of between devices in the sample with defects and devices in the sample that are free of defects.

Since different parts of logic/memory devices may formed by different materials with varying structures, it is desirable that the charge controller be effective a various depths. This requires the charge controller beam to penetrate deeply into the materials and be absorbed. On other words, in order to improve the S/N ratio at different parts of logic/memory devices, multiple beams with different wavelengths may be used so that the charge controller may operate at a shallow layer and at a deeper layer on the wafer with enough photon energy absorption.

Light beams with different wavelengths have different penetration depths (traveling lengths) in materials. The penetration depth δₚ is given by the relationship δₚ=λ₀/(4πκ), where λ₀ is the wavelength of light and κ is the extinction coefficient of the material. Thus longer wavelength light has a greater penetration depth. The longer penetration depth implies that the energy of the light is absorbed less strongly by the material. It should be noted that herein the term “light” is used to refer to the entire electromagnetic spectrum, regardless of whether the light is visible to the human eye, and can include infrared, ultra-violet, x-ray, gamma ray, or radio frequency electromagnetic radiation, among others.

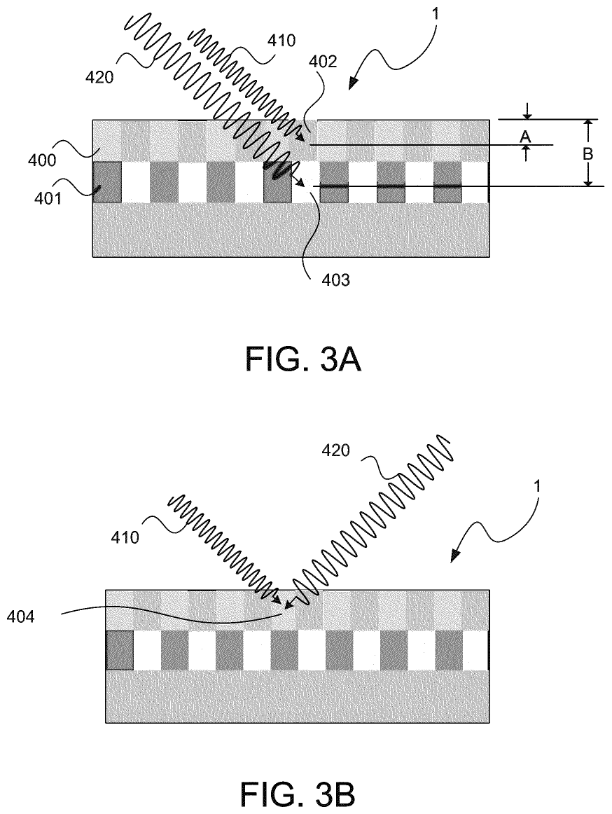

In FIG. 3A, a portion of the sample 1 is shown with various structures 400, 401, 402, etc. at various depths. A short wavelength beam 410 interacts with structure 402 at a first depth A. A longer wavelength beam 420 is less strongly absorbed and interacts with structure 403 at a second depth B that is deeper than A. FIG. 3B shows a different case in which beams with different wavelengths interact differently with the bulk material of the sample. A short wavelength beam 410 interacts predominantly by modifying the electrical characteristics of the material in structure 404 while a second beam 420 with a longer wavelength interacts by heating the material. Using laser beams with different wavelengths provides the ability to transmit more laser/optical energy transmitted into the materials, which makes the electrical/thermal properties of the charge controller more effective.

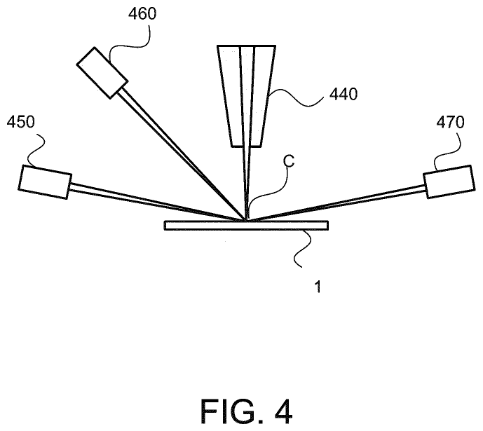

Any of various arrangements may be used to project multiple beams of differing wavelengths onto the e-beam center on the sample. For example, as shown in FIG. 4, the beams may be directed to converge on the e-beam center from different ports or directions. A first laser 450 is directed to the center C of an e-beam from an e-beam source 440 on the substrate 1 from a first direction, a second laser 460 is directed to the e-beam center C on the substrate 1 from a second direction, and a third laser 470 is directed to the e-beam center C on the substrate 1 from a third direction. It will be apparent to one of ordinary skill in the art that any number of separate lasers may be used. Two lasers may share the same wavelength as long as another laser is present generating light at a different wavelength.

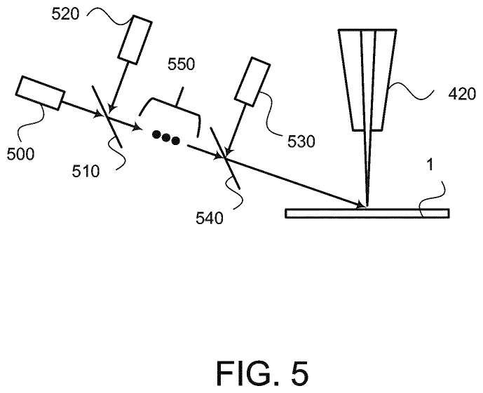

FIG. 5 shows an arrangement in which dichroic mirrors are used to project multiple beams having differing wavelengths along a common optical path. Thus, the light from the first laser 500 strikes the dichroic mirror 510 and passes through it while light from a second laser 520 strikes the dichroic mirror 510 and is reflected by the dichroic mirror 510 to propagate along a beam path which is the same as the beam path of the radiation from the first laser 500. Additional combinations of the laser and dichroic mirror may be added. In the example shown, there is a third laser 530 and a second dichroic mirror 540. The dots 550 indicate that an arbitrary number of such arrangements may be used. It will be apparent to one of ordinary skill in the art that any number of separate lasers may be used. Two lasers may share the same wavelength as long as another laser is present generating light at a different wavelength.

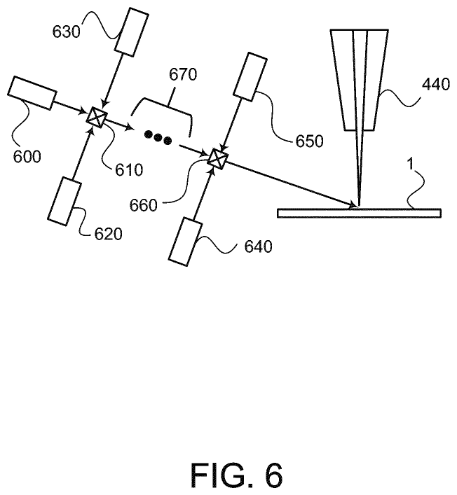

FIG. 6 shows an arrangement in which trichroic prisms are used to project multiple beams having differing wavelengths along a common optical path. Thus, the light from the first laser 600 strikes the trichroic prism 610 and passes through it while light from a second laser 620 strikes the trichroic prism 610 and is reflected by the trichroic prism 610 to propagate along the beam path which is the same as the beam path of the radiation from the first laser. Light from a third laser 630 also strikes the trichroic prism 610 and is reflected to propagate along the common beam path. Additional combinations of the lasers and trichroic prism may be added. In the example shown, there is a fourth laser 640, a fifth laser 650, and a second trichroic prism 660. The dots 670 indicate that an arbitrary number of such arrangements may be used. It will be apparent to one of ordinary skill in the art that any number of separate lasers may be used. Two lasers may share the same wavelength as long as another laser is present generating light at a different wavelength.

Thus, there is disclosed an e-beam inspection system that includes beam emitting sources with two or more wavelengths to help control the surface charge. Beams with different wavelength may be projected into e-beam system as separate beams. The beams with different wavelengths may be combined into one beam with dichroic filters, hot mirrors, cold mirrors, trichroic prisms or other optics that could manipulate beams with different wavelengths together. The wavelengths of the beams may be selected so that they operate at different depths of the substrate. The wavelength of the beams may be selected so that they have different effects in the same portion of the substrate, for example, with one beam predominantly changing the electrical characteristics of the substrate and the other changing the temperature of the substrate.

The embodiments may further be described using the following clauses:

1. Apparatus for inspecting a substrate, the apparatus comprising:

at least one charged particle beam source arranged to project at least one charged particle beam onto a portion of the substrate; and

a plurality of light sources, the plurality of light sources comprising at least
a first light source arranged to project a first beam of light having a first wavelength onto the portion of the substrate; and
a second light source arranged to project a second beam of light having a second wavelength different from the first wavelength onto the portion of the substrate.

2. The apparatus for inspecting a substrate of clause 1 wherein the at least one charged particle beam source comprises an e-beam source.

3. The apparatus for inspecting a substrate of clause 1 or clause 2 wherein the first light source comprises a first laser configured to generate the first beam and the second light source comprises a second laser configured to generate the second beam.

4. The apparatus for inspecting a substrate of clause 1, 2, or 3 wherein the first wavelength is selected to penetrate the portion of the substrate to a first depth and the second wavelength is selected to penetrate the portion of the substrate to a second depth different from the first depth.

5. The apparatus for inspecting a substrate of any one of clauses 1-4 wherein the first wavelength is selected to generate thermal effects in the portion of the substrate and the second wavelength is selected to modify electrical properties in the portion of the substrate.

6. The apparatus for inspecting a substrate of clause 4 wherein the first wavelength is selected to one of generate thermal effects or modify electrical properties in the portion of the wafer at the first depth and the second wavelength is selected to one of generate thermal effects or modify electrical properties in the portion of the wafer at the second depth.

7. The apparatus for inspecting a substrate of any one of clauses 1-6 further comprising a beam combiner arranged to combine the first beam and the second beam into a single beam.

8. The apparatus for inspecting a substrate of clause 7 wherein the beam combiner comprises a dichroic mirror.

9. The apparatus for inspecting a substrate of clause 7 wherein the beam combiner comprises a trichroic prism.

10. A charged particle beam imaging apparatus for imaging a portion of a substrate, the apparatus comprising:

at least one source of at least one beam of charged particles;

a charged particle optical system arranged to focus the at least one beam onto a portion of the substrate; and

an electromagnetic radiation optical system adapted to generate at least a first beam having a first wavelength and a second beam having a second wavelength different from the first wavelength and to focus the first and second beam on the portion of the substrate.

11. The charged particle beam imaging apparatus of clause 10 wherein the source of a beam of charged particles comprises an e-beam source.

12. The charged particle beam imaging apparatus of clause 10 or 11 wherein the electromagnetic radiation optical system comprises a first laser configured to generate the first beam and a second laser configured to generate the second beam.

13. The charged particle beam imaging apparatus of clause 10, 11, or 12 wherein the first wavelength is selected to penetrate the portion of the substrate to a first depth and the second wavelength is selected to penetrate the portion of the substrate to a second depth different from the first depth.

14. The charged particle beam imaging apparatus of any one of clauses 10-13 wherein the first wavelength is selected to generate thermal effects in the portion of the substrate and the second wavelength is selected to modify electrical properties in the portion of the substrate.

15. The charged particle beam imaging apparatus of clause 10 wherein the first wavelength is selected to generate thermal effects in the portion of the substrate at a first depth and the second wavelength is selected to modify electrical properties in the portion of the substrate at a second depth different from the first depth.

16. The charged particle beam imaging apparatus of any one of clauses 10-15 further comprising a beam combiner arranged to combine the first beam and the second beam into a single beam.

17. The charged particle beam imaging apparatus of clause 16 wherein the beam combiner comprises a dichroic mirror.

18. The charged particle beam imaging apparatus of clause 16 wherein the beam combiner comprises a trichroic prism.

19. A method of inspecting a substrate, the method comprising the steps of:

projecting at least one charged particle beam onto a portion of the substrate;

projecting a first beam of light having a first wavelength onto the portion of the substrate; and

projecting a second beam of light having a second wavelength different from the first wavelength onto the portion of the substrate.

20. The method of inspecting a substrate of clause 19 wherein the step of projecting a charged particle beam onto a portion of the substrate is performed using an e-beam source.

21. The method of inspecting a substrate of clause 19 or 20 wherein the step of projecting a first beam of light having a first wavelength onto the portion of the substrate and the step of projecting a second beam of light having a second wavelength different from the first wavelength onto the portion of the substrate are performed concurrently.

22. The method of inspecting a substrate of clause 19, 20, or 21, wherein the step of projecting a first beam of light having a first wavelength onto the portion of the substrate is performed using a first laser and the step of projecting a second beam of light having a second wavelength different from the first wavelength onto the portion of the substrate is performed using a second laser.

23. The method of inspecting a substrate of any one of clauses 19-22 wherein the first wavelength is selected to penetrate the portion of the substrate to a first depth and the second wavelength is selected to penetrate the portion of the substrate to a second depth different from the first depth.

24. The method of inspecting a substrate of any one of clauses 19-23 wherein the first wavelength is selected to generate thermal effects in the portion of the substrate and the second wavelength is selected to modify electrical properties in the portion of the substrate.

25. The method of inspecting a substrate of any one of clauses 19-22 wherein the first wavelength is selected to generate thermal effects in the portion of the wafer at a first depth and the second wavelength is selected to modify electrical properties in the portion of the wafer at a second depth different from the first depth.

26. The method of inspecting a substrate of any one of clauses 19-25 further comprising a step of combining the first beam and the second beam into a single beam.

27. The method of inspecting a substrate of clause 26 wherein the combining step is performed using at least one dichroic mirror.

28. The method of inspecting a substrate of clause 26 wherein the combining step is performed using at least one trichroic prism.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. Apparatus for inspecting a substrate, the apparatus comprising:
at least one charged particle beam source arranged to project at least one charged particle beam onto a portion of the substrate; and
a plurality of light sources, the plurality of light sources comprising at least
a first light source arranged to project a first beam of light having a first wavelength onto the portion of the substrate; and
a second light source arranged to project a second beam of light having a second wavelength different from the first wavelength onto the portion of the substrate.

2. Apparatus for inspecting a substrate as claimed in claim 1, wherein the at least one charged particle beam source comprises an e-beam source.

3. Apparatus for inspecting a substrate as claimed in claim 1, wherein the first light source comprises a first laser configured to generate the first beam and the second light source comprises a second laser configured to generate the second beam.

4. Apparatus for inspecting a substrate as claimed in claim 1, wherein the first wavelength is selected to penetrate the portion of the substrate to a first depth and the second wavelength is selected to penetrate the portion of the substrate to a second depth different from the first depth.

5. Apparatus for inspecting a substrate as claimed in claim 1, wherein the first wavelength is selected to generate thermal effects in the portion of the substrate and the second wavelength is selected to modify electrical properties in the portion of the substrate.

6. Apparatus for inspecting a substrate as claimed in claim 4, wherein the first wavelength is selected to one of generate thermal effects or modify electrical properties in the portion of the wafer at the first depth and the second wavelength is selected to one of generate thermal effects or modify electrical properties in the portion of the wafer at the second depth.

7. Apparatus for inspecting a substrate as claimed in claim 1, further comprising a beam combiner arranged to combine the first beam and the second beam into a single beam.

8. Apparatus for inspecting a substrate as claimed in claim 7, wherein the beam combiner comprises a dichroic mirror.

9. Apparatus for inspecting a substrate as claimed in claim 7, wherein the beam combiner comprises a trichroic prism.

10. A method of inspecting a substrate, the method comprising the steps of:
projecting at least one charged particle beam onto a portion of the substrate;
projecting a first beam of light having a first wavelength onto the portion of the substrate; and
projecting a second beam of light having a second wavelength different from the first wavelength onto the portion of the substrate.

11. A method of inspecting a substrate as claimed in claim 10, wherein the step of projecting a first beam of light having a first wavelength onto the portion of the substrate and the step of projecting a second beam of light having a second wavelength different from the first wavelength onto the portion of the substrate are performed concurrently.

12. A method of inspecting a substrate as claimed in claim 10, wherein the step of projecting a first beam of light having a first wavelength onto the portion of the substrate is performed using a first laser and the step of projecting a second beam of light having a second wavelength different from the first wavelength onto the portion of the substrate is performed using a second laser.

13. A method of inspecting a substrate as claimed in claim 10, wherein the first wavelength is selected to penetrate the portion of the substrate to a first depth and the second wavelength is selected to penetrate the portion of the substrate to a second depth different from the first depth.

14. A method of inspecting a substrate as claimed claim 10, wherein the first wavelength is selected to generate thermal effects in the portion of the substrate and the second wavelength is selected to modify electrical properties in the portion of the substrate.

15. A method of inspecting a substrate as claimed in claim 10, wherein the first wavelength is selected to generate thermal effects in the portion of the wafer at a first depth and the second wavelength is selected to modify electrical properties in the portion of the wafer at a second depth different from the first depth.
